(19) United States
(12) Patent Application Publication
(10) Pub. No.: US 2015/0228518 A1
(43) Pub. Date: Aug. 13, 2015

(54) FUME REMOVAL DEVICE AND SUBSTRATE TREATMENT DEVICE

(71) Applicant: EUGENE TECHNOLOGY CO., LTD., Gyeonggi-do (KR)

(72) Inventor: Jun-Jin Hyon, Gyeonggi-do (KR)

(73) Assignee: EUGENE TECHNOLOGY CO., LTD., Gyeonggi-do (KR)

(21) Appl. No.: 14/427,100

(22) PCT Filed: Sep. 17, 2013
(86) PCT No.: PCT/KR2013/008434

§ 371 Date: Mar. 10, 2015

(30) Foreign Application Priority Data
Sep. 24, 2012 (KR) 10-2012-0105728

(51) Int. Cl. H01L 21/673; H01J 37/32; H01L 21/67

(52) U.S. Cl. CPC H01L 21/67389; H01L 21/67017; H01J 37/32458; H01J 37/32798; H01J 2237/332; H01J 2237/334; H01J 2237/335; H01J 2237/336

(57) ABSTRACT

Provided is a substrate processing apparatus. The substrate processing apparatus includes a process unit in which a process for processing substrates is performed, a loadport on which an accommodation container accommodating the substrates is disposed, a frame disposed between the process unit and the loadport to define an inner space, an internal container having an accommodation space communicating with the internal space and an inlet through which the substrates are loaded into or unloaded from the accommodation space, the internal container having a plurality of discharge holes in a rear surface facing the inlet, an external container disposed outside the internal container to define a discharge space communicating with the accommodation space through the discharge holes, an exhaust hole defined in the external container to communicate with the discharge space, and an exhaust line in which an exhaust pump forcibly exhausting the inside of the accommodation space is disposed, the exhaust line being connected to the exhaust hole.

### TECHNICAL FIELD

The present disclosed herein relates to an apparatus for removing fume and an apparatus for processing a substrate, and more particularly, to an apparatus for removing fume existing on a substrate, which is processed by a predetermined process, through a discharge hole defined in a rear surface of an internal container.

### BACKGROUND ART

Generally, in semiconductor device manufacturing processes, unit processes such as a deposition process, a photolithography process, an etching process, an ion injection process, a polishing process, a cleaning process, and the like may be repeatedly performed on a silicon substrate that is used as a substrate to form circuit patterns having desired electrical properties. Particularly, the cleaning process may be performed to remove foreign substance remaining on the substrate after each of the unit processes is performed. Here, a drying or wet process may be performed according to a kind of foreign substance. In case of the wet cleaning process, a batch-type cleaning process cleaning a plurality of substrate at the same time and a single-wafer-type cleaning process cleaning substrates one by one may be selectively performed as necessary.

In case of the single-wafer-type cleaning process cleaning substrates one by one, a method in which a cleaning solution is supplied onto a substrate while spinning the substrate may be mainly used. Particularly, in case of an apparatus for performing the single-wafer-type cleaning process, the apparatus may include a spin chuck spinning a substrate, a cleaning solution supply unit supplying a cleaning solution onto the substrate, a cleaning container having a closed lower portion to recovery the cleaning solution supplied onto the substrate, and a driving unit rotating the spin chuck. Various kinds of cleaning solutions may be used according to foreign substances to be removed from a surface of the substrate.

For example, various chemicals such as sulfuric acid, hydrofluoric acid, ammonium hydroxide, hydrochloric acid, hydrogen peroxide, dichlorosilane (DCS), and the like may be used as the cleaning solution. As described above, the cleaning solution including the chemicals may cause corrosion or deformation of a cleaning container. Thus, there is required to improve this limitation. Also, the chemical cleaning solution may cause fume during the process. Thus, the fume may be introduced into a front opening unified pod (FOUP) together with the processed substrate to cause faulty substrates.

### DISCLOSURE

### Technical Problem

The present invention provides an apparatus for transferring a processed substrate into a fume removing apparatus to remove fume.

The present invention also provides an apparatus for removing fume generated from a processed substrate to prevent the fume from being introduced into FOUP.

Further another object of the present invention will become evident with reference to following detailed descriptions and accompanying drawings.

### Technical Solution

Embodiments of the present invention provide substrate processing apparatuses including: a process unit in which a process for processing substrates is performed; a loadport on which an accommodation container accommodating the substrates is disposed; a frame disposed between the process unit and the loadport to define an inner space; an internal container having an accommodation space communicating with the internal space and an inlet through which the substrates are loaded into or unloaded from the accommodation space, the internal container having a plurality of discharge holes in a rear surface facing the inlet; an external container disposed outside the internal container to define a discharge space communicating with the accommodation space through the discharge holes; an exhaust hole defined in the external container to communicate with the discharge space; and an exhaust line in which an exhaust pump forcibly exhausting the inside of the accommodation space is disposed, the exhaust line being connected to the exhaust hole.

In some embodiments, the substrate processing apparatuses may further include an air spray unit disposed on the inlet of the internal container to spray air toward the inlet thereby forming an air curtain and isolating the accommodation space from the outside.

In other embodiments, the internal container may include a support vertically stacking the substrates to be spaced a predetermined distance from each other.

In still other embodiments, the substrate processing apparatuses may further include a heater disposed in the accommodation space to heat the substrates.

In even other embodiments, the substrate processing apparatuses may further include a transfer unit transferring the substrates accommodated within the accommodation container into the process unit, the transfer unit transferring the processed substrates from the process unit into the internal container and transferring the substrates, on which fume is removed, from the internal container into the accommodation container.

In yet other embodiments, the process unit may perform a silicon oxide formation process by using dichlorosilane (DCS), and the exhaust pump may forcibly exhaust fume generated from the substrates within the accommodation space.

In other embodiments of the present invention, fume removing apparatuses disposed on a side of substrate manufacturing equipment to remove fume of a substrate include: an internal container having an accommodation space accommodating the substrate on which a predetermined substrate processing process is performed and an inlet through which the substrate is loaded into or unloaded from the accommodation space, the internal container having a plurality of discharge holes in a rear surface facing the inlet; an external container disposed outside the internal container to define a discharge space communicating with the accommodation space through the discharge holes; an exhaust hole defined in the external container to communicate with the discharge space; and an exhaust line in which an exhaust pump forcibly exhausting the inside of the accommodation space is disposed, the exhaust line being connected to the exhaust hole.

In some embodiments, the fume removing apparatuses may further include an air spray unit disposed on the inlet of the internal container to spray air toward the inlet thereby forming an air curtain and isolating the accommodation space from the outside.

In other embodiments, the fume removing apparatuses may further include a heater disposed in the accommodation space to heat the substrates.

### Advantageous Effects

According to the embodiment of the present invention, the fume of the substrate accommodated in the internal container may be removed by using the exhaust hole defined in the exhaust space between the internal container and the external container. Also, since the fume generated from the processed substrate is removed, faulty substrates due to the fume may be prevented, and yield of products may be improved.

### BRIEF DESCRIPTION OF THE DRAWINGS

FIG. 1 is a schematic view of a substrate processing apparatus according to an embodiment of the present invention;

FIG. 2 is a schematic view illustrating a fume removing apparatus of FIG. 1;

FIG. 3 is a cross-sectional view illustrating an installation state within an external container of FIG. 2;

FIG. 4 is a rear view illustrating an internal container of FIG. 3.

FIG. 5 is a schematic view of an exhaust line disposed within a housing of FIG. 2; and

FIG. 6 is a view illustrating a flow state of a gas within the fume removing apparatus of FIG. 2.

### BEST MODE

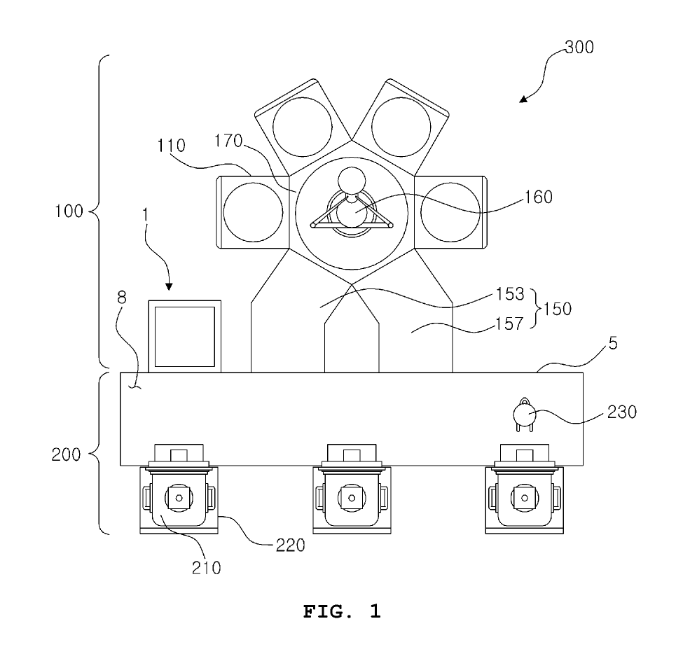

Hereinafter, exemplary embodiments of the present invention will be described in detail with reference to FIGS. 1 to 6. The present invention may, however, be embodied in different forms and should not be constructed as limited to the embodiments set forth herein. Rather, these embodiments are provided so that this disclosure will be thorough and complete, and will fully convey the scope of the present invention to those skilled in the art. In the drawings, the shapes of components are exaggerated for clarity of illustration.

FIG. 1 is a schematic view of a substrate processing apparatus according to an embodiment of the present invention. Referring to FIG. 1, a substrate processing apparatus 300 includes a process unit 100 in which a processing process with respect to a substrate W is performed and an equipment front end module (EFEM) 200 through which the substrate W is loaded into or unloaded from the process unit 100. The process unit 100 includes a plurality of process chambers 110, a transfer chamber 170, a first transfer unit 120, and a loadlock chamber 150.

Each of the process chamber 110 receives the substrate W to perform a semiconductor process, e.g., an etching process, a cleaning process, an ashing process, and the like, thereby processing the substrate W. The transfer chamber 170 may have a substantially polygonal shape when viewed from an upper side. Also, the transfer chamber 170 is connected to each of the process chambers 110 and the loadlock chamber 150. The first transfer unit 120 may be disposed within the transfer chamber 170. The first transfer unit 120 may load the substrate W into each of the process chambers 110 or unload the substrate W from each of the process chambers 110. Also, the first transfer unit 120 may transfer the substrate W between each of the process chambers 110 and the loadlock chamber 150.

The loadlock chamber 150 is disposed between the transfer chamber 170 and the EFEM 200. The loadlock chamber 150 may include a loading chamber 153 in which the substrates W loaded into the process chambers 110 temporarily stay and an unloading chamber 157 in which the processed substrates W loaded from the process chambers 110 temporarily stay. Here, the inside of the loadlock chamber 150 may be converted into the vacuum or atmospheric state. However, the transfer chamber 170 and the process chambers 110 are maintained in the vacuum state. Thus, the loadlock chamber 150 prevents external contaminants from being introduced into the process chambers 110 and the transfer chamber 170.

The EFEM 200 includes a plurality of accommodation containers 210, a plurality of loadports 220, a frame 5, and a second transfer unit 230. The accommodation containers 210 may accommodate the plurality of substrates W. Here, the accommodation containers 210 provide the substrates W that are not provided yet into the process unit 100 and accommodate again the substrates W processed by the process unit 100. The accommodation container 210 is seated on the loadport 220, and the loadport 220 is disposed on a front side of the frame 5 to support the accommodation container 210.

The frame 5 is disposed between the loadport 220 and the loadlock chamber 150 to define an inner space 8. The second transfer unit 230 is disposed in the inner space 8. The second transfer unit 230 transfers the substrate W between the accommodation container 210 seated on the loadport 220 and the process unit 230. The second transfer unit 230 takes the substrate W out of the accommodation container 210 to provide the substrate W into the process unit 230. Also, the second transfer unit 230 receives the processed substrate W from the process unit 230 to transfer the substrate W into the accommodation container 210.

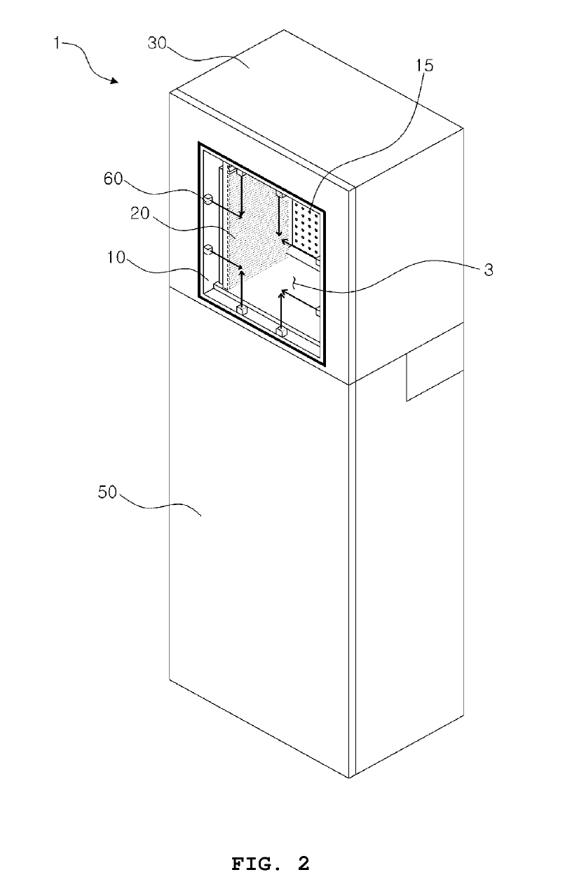

A fan (not shown) and a filter (not shown) may be disposed on an upper portion of the frame 5. The fan allow air to laminar flow from an upper side to a lower side within the frame 5, and the filter removes particles of the air to filter the air. That is, an accommodation space (see reference numeral 3 of FIG. 2) of the fume removing apparatus 1 installed to communicate with a side of the frame 5 has a pressure less than that of the inner space 8 of the frame 5. Thus, the gas within the inner space 8 may flow toward the accommodation space (see reference numeral 3 of FIG. 2).

In case of a single cluster type dichlorosilane (DCS) process for processing a substrate, a chemical reaction may be expressed as follows:

(SiH₂Cl₂+2N₂O→SiO₂+2N↑+2HCl) Reaction Formula (1)

As shown in Reaction Formula (1), when substrates W on which the DCS process is performed are transferred one by one into a front opening unified pod (FOUP), HCl absorbed on a surface of the substrate W reacts with moisture within the EFEM 200 to generate hydrochloric acid. Thus, the hydrochloric acid may corrode a metal within the EFEM 200. Particularly, in case of the single-wafer-type process cleaning the substrates W one by one, the process may be quickly performed when compared to the batch-type process. Thus, the corrosive gas (HCl) generated from the substrate W may increase in remaining amount to significantly corrode peripheral components and devices.

Also, when the fume of the substrate W on which the etching process is performed moves into the accommodation container 210 for accommodating the plurality of substrates W without being removed, the fume may be transferred onto other substrates W within the accommodation container 210 to cause contamination of the substrates W. To solve the above-described limitation, the fume removing apparatus 1 may be provided on a side of the frame 5 to remove the fume and corrosive gas which can contaminate the substrates W. The fume removing apparatus 1 will be described with reference to following drawings.

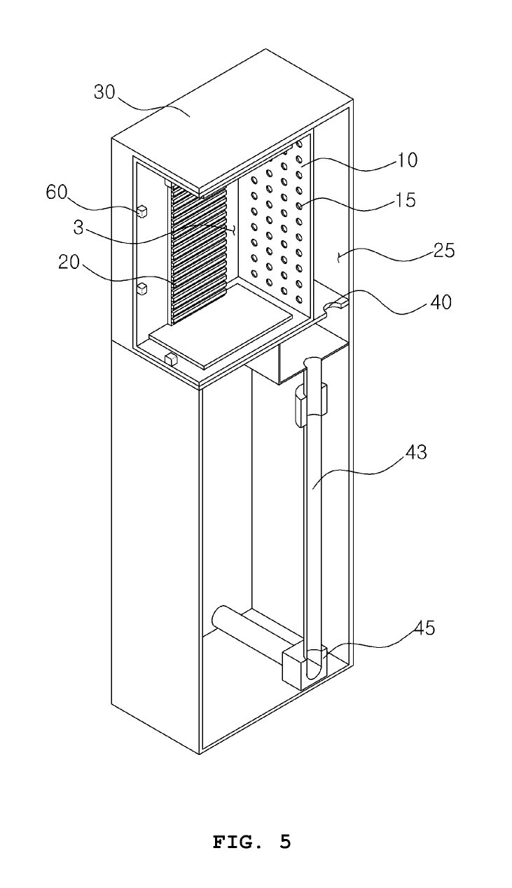

FIG. 2 is a schematic view illustrating a fume removing apparatus of FIG. 1. Referring to FIG. 2, the fume removing apparatus 1 is disposed on a side of the frame 5, and a support member 50 is disposed on a lower portion an external container 30 to support the external container 30. An internal container 10 is disposed on an inner surface of the external container 30. The internal container 10 has an accommodation space 3 communicating with the inner space 8 of the frame 5. Also, the internal container 10 has an inlet through which the substrate W is accessible into the accommodation space 3. The external container 30 has a shape corresponding to an outer surface of the internal container 10. The external container is disposed spaced apart from a rear side of the internal container 10 to define an exhaust space (see reference numeral 25 of FIG. 5). A support 20 accommodating the substrate W is disposed in the accommodation space 3. Thus, the substrate W in which a predetermined processing process is performed is transferred on the support 20 by the second transfer unit 230. The support 20 vertically stacks the processed substrates W. For example, 25 substrates W may be vertically stacked within the support 20.

Air spray nozzles 60 may be disposed along an inlet of the internal container 10. The air spray nozzle 60 may be provided in plurality at preset positions. Each of the air spray nozzles 60 sprays air toward the inlet to form an air curtain, thereby isolating the accommodation space 3 from the inner space 8 of the frame 5. The air spray nozzles 60 may receive gas from a gas storage tank (not shown) connected to an air supply tube. Also, a valve (not shown) may be opened or closed to adjust an air supply rate. The gas storage tank may be replaced with an inert gas such as N₂ and Ar.

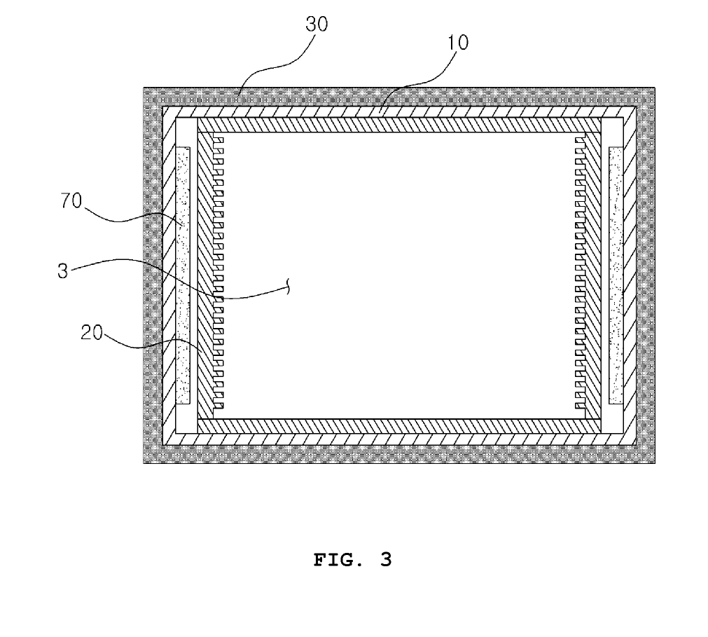

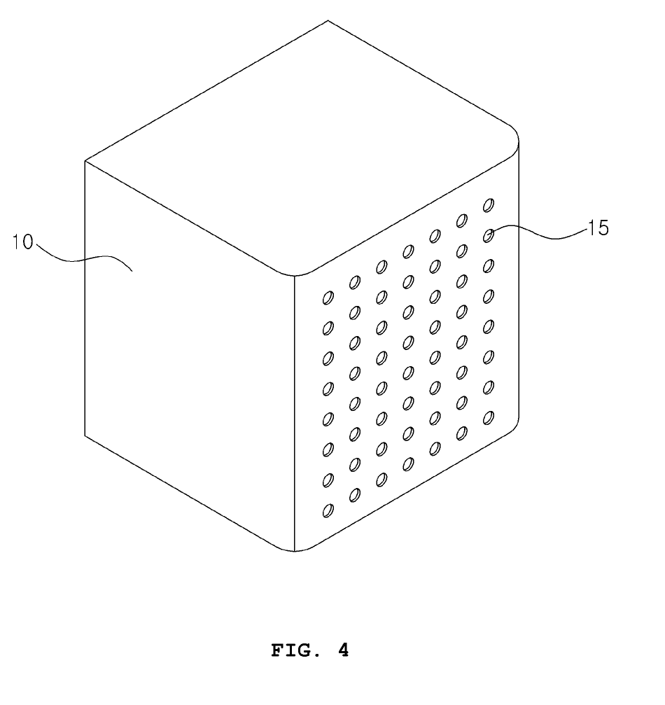

FIG. 3 is a cross-sectional view illustrating an installation state within the external container of FIG. 2, and FIG. 4 is a rear view illustrating the internal container of FIG. 3. FIG. 5 is a schematic view of an exhaust line disposed within the housing of FIG. 2.

As shown in FIG. 3, the external container 30 is disposed outside the internal container 10. A heater 70 is disposed on each of both side surfaces of the internal container 10 to heat a substrate W. The support 20 is disposed in the accommodation space 3 of the internal container 10 to accommodate the substrate W. The heater 70 may generate heat to increase a temperature of the accommodation space 3, and thus, the fume on the substrate W may be removed. The heater 70 may be disposed between the internal container 10 and the support 20. Alternatively, the heater 70 may be built in the internal container 10.

As described above, the internal container 10 has the accommodation space 3 communicating with the inner space 8 of the frame 5 and the inlet through which the substrate W is loaded into or unloaded from the accommodation space 3. Also, as shown in FIGS. 4 and 5, a plurality of discharge holes 15 are defined in a rear surface facing the inlet of the internal container 10. The inner space 8 of the frame 5 may be maintained at a pressure greater than that of the accommodation space 3 of the internal container 10 by the fan disposed on the upper portion of the frame. Thus, the gas may form an air current toward the discharge holes 15 of the internal container from an inlet-side of the internal container 10.

The exhaust space 25 is defined between the rear surface of the internal container 10 and the external container 30. An exhaust hole 40 is defined in a bottom surface of the external container 30 within the exhaust space 25. The support member 50 is disposed on a lower portion of the external container 30 to support the external container 30. The support member 50 may have an opening. The opening is defined under the exhaust hole 40 to communicate with the exhaust hole 40.

An exhaust line 43 may be disposed under the exhaust hole 40. The exhaust line 43 may be connected to an exhaust pump 45 to forcibly discharge the gas within the accommodation space 3 to the outside. That is, the inside of the accommodation space 3 may increase in temperature by using the heater 70 disposed in the internal container 10 to remove the fume generated on the substrate W. In addition, the fume within the accommodation space 3 may be pumped to the exhaust hole 40 through the discharge hole 15 defined in the rear side of the internal container 10 to discharge the fume to the outside, thereby preventing the substrate W accommodated within the accommodation space 3 from corroding. Thus, occurrence of faulty substrates may be prevented, and yield of products may be improved.

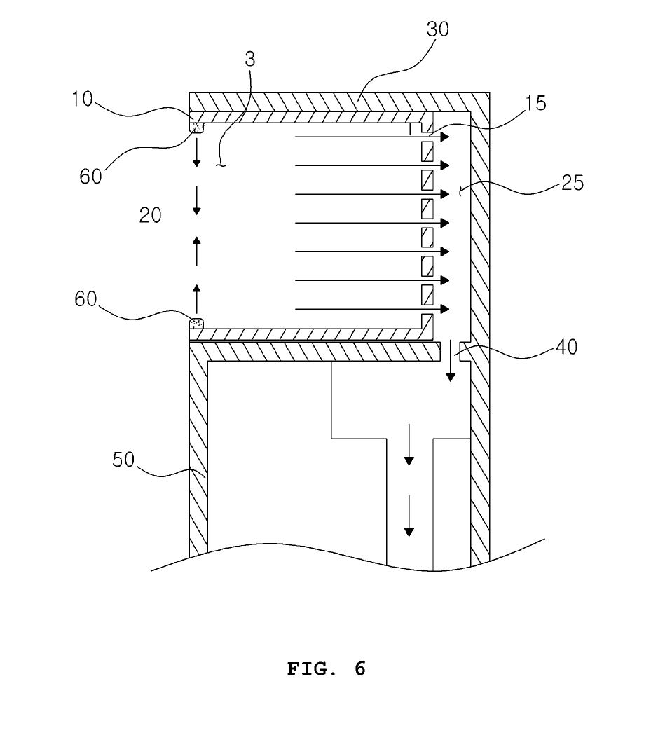

FIG. 6 is a view illustrating a flow state of a gas within the fume removing apparatus of FIG. 2. As described above, the air spray nozzles 60 are disposed on the inlet of the internal container 10 to spray air toward the inlet, thereby form the air curtain, thereby isolating the accommodation space 3 from the inner space 8. The exhaust line 43 is connected to the exhaust pump 45 to pump the inside of the exhaust hole 40. Thus, the fume within the accommodation space 3 flows into the exhaust space 25 through the discharge hole 15 of the internal container 10. The fume gas may be forcibly exhausted into the exhaust hole 40 through the exhaust space 25 to prevent the fume gas from flowing backward, thereby completely removing the contaminant sources within the accommodation space 3.

Although the present invention is described in detail with reference to the exemplary embodiments, the invention may be embodied in many different forms. Thus, technical idea and scope of claims set forth below are not limited to the preferred embodiments.

### INDUSTRIAL APPLICABILITY

The present invention is applicable for a semiconductor manufacturing apparatus and a semiconductor manufacturing method in a various type.

What is claimed is:

1. A substrate processing apparatus comprising:
a process unit in which a process for processing substrates is performed;
a loadport on which an accommodation container accommodating the substrates is disposed;
a frame disposed between the process unit and the loadport to define an inner space;
an internal container having an accommodation space communicating with the internal space and an inlet through which the substrates are loaded into or unloaded from the accommodation space, the internal container having a plurality of discharge holes in a rear surface facing the inlet;
an external container disposed outside the internal container to define a discharge space communicating with the accommodation space through the discharge holes;
an exhaust hole defined in the external container to communicate with the discharge space; and
an exhaust line in which an exhaust pump forcibly exhausting the inside of the accommodation space is disposed, the exhaust line being connected to the exhaust hole.

2. The substrate processing apparatus of claim 1, further comprising an air spray unit disposed on the inlet of the internal container to spray air toward the inlet thereby forming an air curtain and isolating the accommodation space from the outside.

3. The substrate processing apparatus of claim 1, wherein the internal container comprises a support vertically stacking the substrates to be spaced a predetermined distance from each other.

4. The substrate processing apparatus of claim 1, further comprising a heater disposed in the accommodation space to heat the substrates.

5. The substrate processing apparatus of claim 1, further comprising a transfer unit transferring the substrates accommodated within the accommodation container into the process unit, the transfer unit transferring the processed substrates from the process unit into the internal container and transferring the substrates, on which fume is removed, from the internal container into the accommodation container.

6. The substrate processing apparatus of claim 1, wherein the process unit performs a silicon oxide formation process by using dichlorosilane (DCS), and
the exhaust pump forcibly exhausts fume generated from the substrates within the accommodation space.

7. A fume removing apparatus disposed on a side of substrate manufacturing equipment to remove fume of a substrate, the fume removing apparatus comprising:
an internal container having an accommodation space accommodating the substrate on which a predetermined substrate processing process is performed and an inlet through which the substrate is loaded into or unloaded from the accommodation space, the internal container having a plurality of discharge holes in a rear surface facing the inlet;
an external container disposed outside the internal container to define a discharge space communicating with the accommodation space through the discharge holes;
an exhaust hole defined in the external container to communicate with the discharge space; and
an exhaust line in which an exhaust pump forcibly exhausting the inside of the accommodation space is disposed, the exhaust line being connected to the exhaust hole.

8. The fume removing apparatus of claim 7, further comprising an air spray unit disposed on the inlet of the internal container to spray air toward the inlet thereby forming an air curtain and isolating the accommodation space from the outside.

9. The fume removing apparatus of claim 7, further comprising a heater disposed in the accommodation space to heat the substrates.
